(19) United States
(12) Patent Application Publication
(10) Pub. No.: US 2025/0226225 A1
(43) Pub. Date: Jul. 10, 2025

(54) METHOD FOR PRODUCING A STRUCTURE COMPRISING AT LEAST TWO CHIPS ON A SUBSTRATE

(71) Applicant: Soitec, BERNIN (FR)

(72) Inventor: Bruno Ghyselen, BERNIN (FR)

(21) Appl. No.: 18/853,564

(22) PCT Filed: Apr. 3, 2023
(86) PCT No.: PCT/FR2023/050472

§ 371 Date: Oct. 2, 2024

(30) Foreign Application Priority Data
Apr. 4, 2022 (FR) FR2203035

(51) Int. Cl. H01L 21/18; H01L 21/304; H01L 21/306; H01L 21/308; H01L 21/683

(52) U.S. Cl. CPC H01L 21/185; H01L 21/304; H01L 21/30604; H01L 21/308; H01L 21/6835; H01L 2221/68363

(57) ABSTRACT

A method for manufacturing a structure comprising at least two chips on a receiver substrate comprises: forming a pseudo-donor substrate by placing at least one tile of at least one donor substrate on a support substrate; bonding the pseudo-donor substrate to a receiver substrate via the tiles so that each tile at least partially covers at least two different zones of interest of the receiver substrate; transferring a portion of the tiles to the receiver substrate; at least one step of chemical-mechanical polishing of the tiles of the pseudo-donor substrate and/or of the tile portions transferred to the receiver substrate; after the at least one step of chemical-mechanical polishing, a removal of material from the tile portions so as to divide each tile portion into at least two chips each arranged on a respective zone of interest.

### CROSS-REFERENCE TO RELATED APPLICATIONS

This application is a national phase entry under 35 U.S.C. § 371 of International Patent Application PCT/FR2023/050472, filed Apr. 3, 2023, designating the United States of America and published as International Patent Publication WO 2023/194679 A1 on Oct. 12, 2023, which claims the benefit under Article 8 of the Patent Cooperation Treaty of French Patent Application Serial No. FR2203035, filed Apr. 4, 2022.

### TECHNICAL FIELD

The present disclosure relates to a process for fabricating a structure comprising at least two chips on a substrate.

### BACKGROUND

In the field of microelectronics, optics or optoelectronics, the design of multilayer structures sometimes requires tiles, in the form of portions of a layer of a donor substrate, to be transferred to a receiver substrate.

This type of process is generally referred to as a tiling process, and involves partial transfer of a layer taken from the donor substrate to form one or more tiles arranged in a pattern or at a predetermined position on the receiver substrate.

Such tiling may be made necessary by a difference in size between the donor substrate and the receiver substrate. Specifically, on account of this difference in size, it is not possible to transfer an entire layer of the donor substrate to the receiver substrate.

A well-known layer transfer process is the Smart Cut™ process, in which, by implanting atomic species in the donor substrate, a weakened zone delimiting the layer to be transferred is formed, the donor substrate is bonded to the receiver substrate and the donor substrate is detached along the weakened zone to transfer the layer from the donor substrate to the receiver substrate. However, that process assumes that the donor substrate and the receiver substrate are the same size.

But, while silicon substrates with a relatively large size, typically a diameter of 300 mm, are available, other materials of interest currently only exist in the form of bulk substrates of smaller size, for example, with a diameter of 10 cm or 15 cm. Furthermore, these materials of interest are sometimes particularly expensive, and so it is desirable to minimize the potential waste formed during the transfer. Such is the case, in particular, for III-V semiconductor materials, comprising nitrides (for example, with regard to binary compounds, indium nitride (InN), gallium nitride (GaN) and aluminum nitride (AlN)), arsenides (for example, with regard to binary compounds, indium arsenide (InAs), gallium arsenide (GaAs) and aluminum arsenide (AlAs)), and phosphides (for example, with regard to binary compounds, indium phosphide (InP), gallium phosphide (GaP) and aluminum phosphide (AlP)).

Rather than transferring an entire layer of the donor substrate, a solution based on the Smart Cut™ process involves forming an intermediate substrate known as a pseudo-donor substrate, by taking from at least one donor substrate one or more tiles and transferring the tiles to a support substrate having a diameter identical to that of the receiver substrate. The process then comprises forming, by implanting atomic species, a weakened zone in each tile, bonding the pseudo-donor substrate to the receiver substrate via the tiles, and detaching each tile along the weakened zone so to as transfer a portion of each tile to the receiver substrate.

During this process, it is generally necessary to polish the tiles, after the formation of the pseudo-donor substrate and/or after the transfer of the portions of tiles to the receiver substrate. Such polishing, which is typically a chemical-mechanical polishing (CMP), aims to planarize the free surface of the tiles or tile portions.

One particular difficulty arises when the tiling is not very dense, i.e., when the degree of coverage of the tiles on the receiver substrate, which corresponds to the ratio of the total surface area of the tiles to the total surface area of the receiver substrate, is less than 50%, or indeed less than 30%. In that situation, there is a large distance, typically of the order of a few millimeters, between the tiles on the pseudo-donor substrate and on the receiver substrate.

However, the polishing cloth that is applied against the tiles is capable of deforming at the recesses formed by the spaces between the tiles. This deformation results in polishing height differences between tiles and an overconsumption of material on the edges of the tiles compared to at their center.

These inhomogeneities generated by the polishing are detrimental to the subsequent use of the tiles for forming electronic, optical or optoelectronic components.

### BRIEF SUMMARY

An aim of the present disclosure is to design a process for fabricating a structure comprising at least two chips on a support substrate, which makes it possible to overcome the abovementioned polishing defects.

To this end, the present disclosure proposes a process for fabricating a structure comprising at least two chips on a receiver substrate, comprising:
forming a pseudo-donor substrate by placing at least one tile of at least one donor substrate on a support substrate;
bonding the pseudo-donor substrate to a receiver substrate via the tiles so that each tile at least partially covers at least two different zones of interest of the receiver substrate;
transferring a portion of the tiles to the receiver substrate;
at least one step of chemical-mechanical polishing of the tiles of the pseudo-donor substrate and/or of the tile portions transferred to the receiver substrate;
after the at least one step of chemical-mechanical polishing, a removal of material from the tile portions so as to divide each tile portion into at least two chips each arranged on a respective zone of interest.

The fact of resizing the tile portions after they have been transferred to the receiver substrate to form the chips makes it possible to increase the density of the tiles on the pseudo-donor substrate and to reduce the distances between tiles and, after the transfer, distances between tile portions. Therefore, the polishing defects linked to these excessively large distances between the tiles or between the transferred tile portions are minimized.

After the etching step, the degree of coverage of the chips on the receiver substrate, i.e., the ratio of the total surface area of the chips to the total surface area of the receiver substrate, is advantageously less than 50%, preferably less than 30%.

Particularly advantageously, the degree of coverage of the tiles on the pseudo-donor substrate, i.e., the ratio of the total surface area of the tiles to the total surface area of the support substrate, is greater than 50%, preferably greater than 75%.

Each tile may have a side with a length greater than or equal to 5 mm, preferably greater than or equal to 8 mm, and preferably greater than or equal to 10 mm.

Furthermore, each chip may have a side with a length less than or equal to 5 mm, preferably less than or equal to 3 mm, and preferably less than or equal to 1 mm.

Particularly advantageously, the distance between two adjacent tiles is less than or equal to 3 mm, preferably less than or equal to 1 mm.

The distance between two adjacent chips may, on the other hand, be greater than or equal to 3 mm, preferably greater than or equal to 5 mm.

In certain embodiments, each tile at least partially covers two different zones of interest of the receiver substrate and a chip is formed, from the tile, on each respective zone of interest.

In other embodiments, each tile at least covers a respective corner of four different zones of interest of the receiver substrate arranged in a square or in a rectangle, and a chip is formed, from the tile, on each corner of the respective zone of interest.

In other embodiments, each tile is in the form of a strip at least partially covering at least three aligned zones of interest of the receiver substrate and a chip is formed, from the tile, on each respective zone of interest.

Particularly advantageously, the support substrate and the receiver substrate have substantially identical diameters, greater than the diameter of the donor substrate.

The pseudo-donor substrate may be bonded to the receiver substrate by molecular adhesion.

In one preferred embodiment, the transfer of each tile portion comprises, in succession, forming a weakened zone by implanting atomic species in each tile of the pseudo-donor substrate to define a tile portion to be transferred, bonding the pseudo-donor substrate to the receiver substrate via the tiles, and detaching each tile along the weakened zone.

In other embodiments, the transfer of each tile portion comprises a thinning by grinding and/or etching of each tile of the pseudo-donor substrate.

Each tile may have a thickness of between 20 μm and 1000 μm, preferably between 100 μm and 700 μm, and the transferred portion of each tile may have a thickness of between 30 nm and 1.5 μm.

Each tile may comprise:
a semiconductor material, such as a III-V material, in particular, indium nitride (InN), gallium nitride (GaN), aluminum nitride (AlN), indium arsenide (InAs), gallium arsenide (GaAs), aluminum arsenide (AlAs), indium phosphide (InP), gallium phosphide (GaP) or aluminum phosphide (AlP), or a IV or IV-IV material, in particular, germanium or silicon carbide (SiC),
a piezoelectric material, such as lithium tantalate (LiTaO₃), lithium niobate (LiNbO₃), potassium-sodium niobate (KₓNa₁₋ₓNbO₃ or KNN), barium titanate (BaTiO₃), quartz, lead zirconate titanate (PZT), a compound of lead-magnesium niobate and of lead titanate (PMN-PT), zinc oxide (ZnO), aluminum nitride (AlN) or aluminum-scandium nitride (AlScN), and/or
an electrically insulating material, such as diamond, strontium titanate, yttria-stabilized zirconia or sapphire.

In some embodiments, the process comprises a step of forming, by epitaxy, at least one epitaxial layer on each tile portion, the removal of material to provide each tile portion into chips being carried out after the epitaxy step.

In some embodiments, the removal of material comprises:
forming a mask comprising a protective film partially covering the tile portions in a pattern defining the chips in each tile portion and at least one opening defining a space to be formed between two chips;
etching each tile portion through each opening of the mask so as to form the space for separating the chips from one another.

The etching may be carried out using an etching solution and the mask is formed of a photoresist.

Alternatively, the etching may be carried out using an ion beam and the mask is formed of a metal.

In other embodiments, the removal of material is carried out selectively by a focused ion beam, the beam being controlled in order to sweep only the regions of the tile portions to be removed.

### BRIEF DESCRIPTION OF THE DRAWINGS

Other features and advantages of the present disclosure will emerge from the detailed description that follows, with reference to the accompanying drawings, in which:

FIG. 1 is a top view of the receiver substrate on which the zones of interest are depicted;

FIG. 2 illustrates a step of taking tiles from a donor substrate;

FIG. 3 illustrates a step of placing the tiles on a support substrate to form a pseudo-donor substrate;

FIG. 4 illustrates a step of formation a weakened zone in the tiles;

FIG. 5 illustrates a step of bonding the pseudo-donor substrate to a receiver substrate via the tiles;

FIG. 6 illustrates a step of transferring portions of tiles to the second support substrate following the detachment of the tiles along the weakened zone;

FIG. 7 illustrates a step of forming a mask on the tile portions so as to delimit the chips to be formed;

FIG. 8 illustrates a step of etching the zones of the tiles not protected by the mask to form the chips;

FIG. 9 illustrates a step of removing the protective film after the etching;

FIG. 10A illustrates an embodiment wherein each tile partly covers two adjacent zones of interest, and FIG. 10B illustrates an example of the distribution of the chips formed from the tiles;

FIG. 11A illustrates an embodiment wherein each tile partly covers several aligned zones of interest, and FIG. 11B illustrates an example of the distribution of the chips formed from the tiles;

FIG. 12A illustrates an embodiment wherein each tile partly covers four zones of interest arranged in a square, and FIG. 12B illustrates an example of the distribution of the chips formed from the tiles.

For the sake of legibility, the drawings have not necessarily been drawn to scale. Furthermore, the number and shape of the zones of interest, of the tiles and of the chips depicted in the drawings are given only by way of illustration.

### DETAILED DESCRIPTION

The present disclosure proposes to form a structure comprising at least two chips on a receiver substrate, wherein the polishing inhomogeneities are avoided, even in the case where the chips are spaced a relatively large distance apart, and/or are not very densely distributed on the receiver substrate, using a substrate known as a pseudo-donor substrate comprising tiles intended to each form at least two chips, the chips being distributed over at least two different zones of interest of the receiver substrate. The pseudo-donor substrate is bonded to the receiver substrate via the tiles, so as to transfer a portion of the tiles to the receiver substrate. Next, removal of material on each tile, notably between the chips, makes it possible to form each chip.

The term “not very densely” is understood in the present text to mean that the degree of coverage of the chips on the receiver substrate, which corresponds to the ratio of the total surface area of the chips to the total surface area of the receiver substrate, is typically less than 50%, or even less than 30%, and/or that the distance between two adjacent chips is greater than or equal to 3 mm, or indeed greater than or equal to 5 mm.

The term “zone of interest” is understood in the present text to mean a zone of the receiver substrate intended to subsequently form an electronic circuit different from the electronic circuit formed in an adjacent zone. In particular, in a subsequent step of fabricating the electronic circuits, the receiver substrate can be cut to form individual chips.

The zones of interest are not necessarily visible on the receiver substrate; they may, in particular, be defined on a plane indicating the location of each component on the receiver substrate at each step of the fabrication process. The location of the zones of interest on the receiver substrate is connected to the plane by way of a reference frame of the receiver substrate, i.e., a system of coordinates attached to the receiver substrate, and which makes it possible to define the position of each point of the surface of the receiver substrate. For example, the reference frame may comprise a datum point that is able to be located on an edge of the receiver substrate, such as a notch conventionally used in the semiconductor industry, and two orthogonal axes extending in the plane of the substrate, one of the axes extending diametrically from the notch and the other axis intersecting the first axis at the center of the substrate.

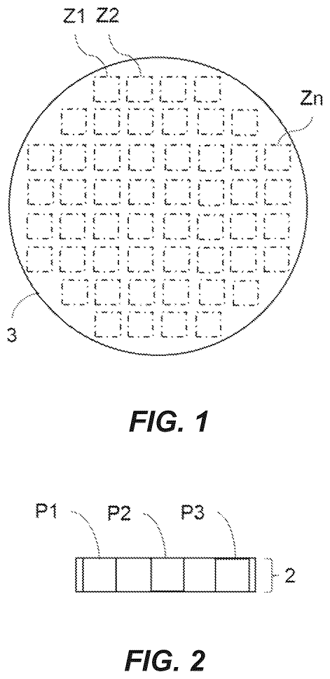

FIG. 1 illustrates an example of the distribution of the zones of interest on a receiver substrate. The receiver substrate 3 has a plurality of zones of interest Z1, Z2, Zn (n being an integer of between 1 and the total number of zones of interest) delimited by dotted lines. These zones are not necessarily marked on the surface of the receiver substrate but the location of each zone of interest in a reference frame of the receiver substrate is known.

In the example illustrated in FIG. 1, the zones of interest all have an identical rectangular shape and are arranged on the receiver substrate in rows and columns to form a grid. However, in other embodiments that are not illustrated, the zones of interest may have different sizes and/or shapes.

The transfer process involves at least one chemical-mechanical polishing of the tiles. Such a polishing may be carried out after placing the tiles on the support substrate to form the pseudo-donor substrate, before bonding to the receiver substrate, on the tile portions transferred to the receiver substrate, or even both on the tiles of the pseudo-donor substrate and on the tile portions transferred to the receiver substrate.

The fact that the tiles are sized to form at least two chips makes it possible to increase the degree of coverage of the tiles and/or to decrease the distance between tiles on the pseudo-donor substrate relative, respectively, to the degree of coverage of the chips on the receiver substrate, and the distance between chips.

Thus, the degree of coverage of the tiles on the pseudo-donor substrate, i.e., the ratio of the total surface area of the tiles to the total surface area of the support substrate, is advantageously greater than 50%, preferably greater than 75%. The receiver substrate may have a diameter substantially identical to that of the support substrate. In this case, this degree of coverage will also be that of the tile portions transferred to the receiver substrate.

Advantageously, the distance between two adjacent tiles is less than or equal to 3 mm, preferably less than or equal to 1 mm.

Furthermore, the pseudo-donor and receiver substrates may have the shape of a relatively thin disc typically having a thickness of a few hundreds of μm (commonly referred to as a “wafer” in the microelectronics field) or a rectangular shape or any geometric shape.

Consequently, the tiles (and the transferred tile portions) are advantageously distributed sufficiently densely for the chemical-mechanical polishing not to produce thickness inhomogeneities between tiles or transferred tile portions. Specifically, the deformation of the polishing cloth between adjacent tiles is minimized, so that the polishing is substantially uniform over the entire surface of the tiles or tile portions.

It is only after this polishing step that the chips are formed by removal of material from the tile portions transferred to the receiver substrate. This removal of material results in a reduction in the density of the chips relative to that of the tiles but, as long as no further step of chemical-mechanical polishing of the chips has to be carried out, it does not lead to a risk of loss of homogeneity of the thickness and of the shape of the chips.

The removal of material can be carried out by various techniques, which are known per se.

Some techniques use a mask to protect the surface of the chips and expose the surface of the tile portions intended to be removed by application of an etchant.

Particularly advantageously, the mask is formed by photolithography, the protective film then being formed from a photoresist that is resistant to the etchant, which is a chemical etching composition. As photolithography is very accurate, it therefore makes it possible to guarantee that the chips have the desired shape and position.

Alternatively, the etchant is an ion beam (technique known as “sputtering”). The mask may comprise a metal protective film or a photoresist, which protects the material of the tiles from the ion beam in the zones covered by the protective film.

The mask is removed after the tile portions have been etched over all or part of their thickness.

It will be noted that it is possible to do away with the use of a mask if use is made of a selective etching process employing a controlled focused etching ion beam for only sweeping over the zones of the tile portions that are to be eliminated.

The pseudo-donor substrate can be produced by placing the tiles one by one, or in small groups of tiles, on the support substrate, for example, by the “Pick and Place” process; on the other hand, the transfer of the tiles from the pseudo-donor substrate to the receiver substrate can be carried out simultaneously.

The process thus makes it possible to subdivide a tile into several smaller chips, extending over several different zones of interest, which are preferably adjacent. The process thus has the advantage of forming chips of very small dimensions without having to place them individually on the receiver substrate, and while avoiding the problems of inhomogeneities due to chemical-mechanical polishing if the chips are not very densely distributed.

For example, each tile initially has a side with a length greater than or equal to 5 mm, preferably greater than or equal to 8 mm, and preferably greater than or equal to 10 mm.

Advantageously, the tiles are made of a material that is not commercially available in the form of a donor substrate with large dimensions. Thus, the donor substrate may have a diameter less than 30 cm, for example, around 10 or 15 cm.

Such is the case, in particular, for III-V semiconductor materials, comprising nitrides (for example, with regard to binary compounds, indium nitride (InN), gallium nitride (GaN) and aluminum nitride (AlN)), arsenides (for example, with regard to binary compounds, indium arsenide (InAs), gallium arsenide (GaAs) and aluminum arsenide (AlAs)), and phosphides (for example, with regard to binary compounds, indium phosphide (InP), gallium phosphide (GaP) and aluminum phosphide (AlP)).

This is also the case for IV or IV-IV semiconductor compounds, for example, germanium and silicon carbide.

The tiles may also be made of a piezoelectric material, for example, lithium tantalate (LiTaO₃) or else lithium niobate (LiNbO₃), potassium-sodium niobate (KₓNa₁₋ₓNbO₃ or KNN), barium titanate (BaTiO₃), quartz, lead zirconate titanate (PZT), a compound of lead-magnesium niobate and of lead titanate (PMN-PT), zinc oxide (ZnO), aluminum nitride (AlN) or aluminum-scandium nitride (AlScN) (non-limiting list).

The tiles may also be made of an electrically insulating material, for instance, diamond, strontium titanate (SrTiO₃), yttria-stabilized zirconia (YSZ) or else sapphire.

FIGS. 2 to 9 schematically illustrate the formation of a pseudo-donor substrate comprising the tiles placed on a first support substrate and the transfer of the tile portions to a receiver substrate, then the division of each tile portion into at least two chips.

With reference to FIG. 2, tiles P1-P3 are cut from a donor substrate 2. The tiles can be cut using any technique known to those skilled in the art. It may, in particular, be carried out by sawing and/or cleavage, or else by laser cutting. It may also, for example, be combined with a step of partial plasma etching of the cutting lines, a technique also known as “plasma dicing.”

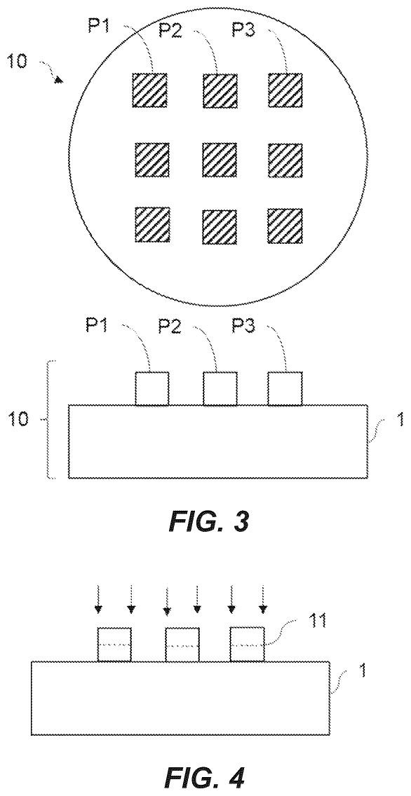

FIG. 3 illustrates the placing of the tiles taken from the donor substrate in FIG. 2 on a support substrate 1 to form a pseudo-donor substrate 10.

Placing may also be carried out using the “Pick and Place” technique, in which a robot takes hold of a tile, or a group of tiles, previously cut from the donor substrate and places it at a predetermined location on the support substrate.

In certain embodiments, each tile adheres to the support substrate by molecular adhesion. To this end, surface treatments of the tiles and/or of the support substrate may be carried out beforehand to promote good molecular adhesion. These treatments may comprise, in particular, cleaning, the deposition of a bonding layer such as a silicon oxide (SiO₂), plasma activation before bonding, and annealing.

In other embodiments (not illustrated), the bonding of the tiles to the support substrate may involve an intermediate bonding layer, for example, a polymer bonding layer, a eutectic bonding layer or a ceramic bonding layer.

The support substrate 1 advantageously has a diameter or dimensions greater than those of the donor substrate 2. For example, the support substrate 1 may have the shape of a disc having a diameter on the order of 300 mm.

FIG. 4 illustrates the formation of a weakened zone in the tiles P1-P3 to delimit a surface portion of the tiles that is intended to be transferred to a receiver substrate. As depicted by the arrows, the weakened zone 11 is advantageously formed by the implantation of atomic species, such as hydrogen and/or helium, in the tiles, at a depth corresponding to the thickness of the layer to be transferred.

Optionally, the pseudo-donor substrate may be the subject of a chemical-mechanical polishing of the surface of the tiles.

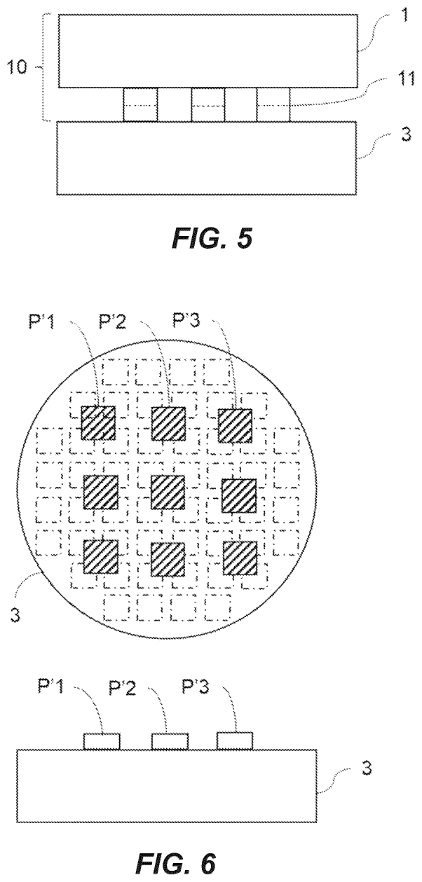

FIG. 5 illustrates the bonding of the pseudo-donor substrate in FIG. 3 to a receiver substrate via the tiles.

During this bonding, the two substrates are positioned relative to one another so that each tile of the pseudo-donor substrate 10 at least partially covers at least two different zones of interest of the receiver substrate 3.

In the example illustrated, each tile partially covers four zones of interest arranged in a square or in a rectangle, i.e., the four zones of interest belong to two adjacent rows and to two adjacent columns, the centers of the four zones of interest forming the four vertices of a square or of a rectangle. Each tile therefore covers not only a portion of the surface of the zones of interest but also the surface of the receiver substrate located between the zones of interest, which has, in this example, a cross shape. In general, to optimize the surface of the receiver substrate and minimize the losses of material, the distance between zones of interest is minimized. The surface of each zone of interest covered by the tile is adapted as a function of the size of the components to be formed in or on the chip or zone of interest.

Particularly advantageously, each tile adheres to the receiver substrate 3 by molecular adhesion. To this end, surface treatments of the tiles and/or of the receiver substrate may be carried out beforehand to promote good molecular adhesion. These treatments may comprise, in particular, cleaning, the deposition of a bonding layer such as a silicon oxide (SiO₂), plasma activation before bonding, polishing and annealing, preferably at low temperature (meaning typically below 300° C.).

The support substrate 1 and the receiver substrate 3 advantageously have substantially the same diameter, for example, around 300 mm.

Next, with reference to FIG. 6, the tiles are detached along the weakened zone 11 in order to transfer the tile portions P′1, P′2, P′3 delimited by the weakened zone to the receiver substrate.

The tiles placed on the support substrate typically have a thickness of between 20 μm and 1000 μm, preferably between 100 μm and 700 μm. The transferred portion of each tile generally has a thickness of between 30 nm and 1.5 μm.

According to an alternative to the Smart Cut™ process that has just been described, the tile portions may be obtained by thinning, by grinding and/or etching, each tile of the pseudo-donor substrate after bonding of the pseudo-donor substrate to the receiver substrate. However, one advantage of the Smart Cut™ process is to minimize the loss of material, it being possible for the pseudo-donor substrate to optionally be recycled and used to once more transfer tile portions to the same receiver substrate or to another receiver substrate.

Optionally, after transferring the tile portions to the receiver substrate, it is possible to carry out a chemical-mechanical polishing of the surface of the tile portions.

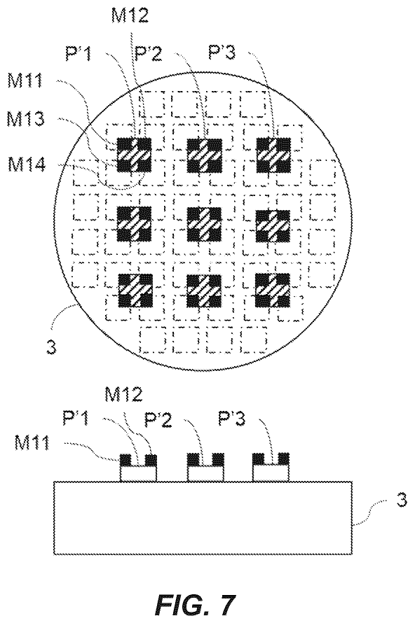

FIG. 7 illustrates the formation, for example, by photolithography, of a mask comprising a protective film M11, M12, M13, M14 partially covering each tile portion and openings extending between the portions of the protective film.

The protective film is configured to define a pattern corresponding to the geometry and to the location of each chip on each respective zone of interest.

The openings typically correspond to the surface of the receiver substrate located between the zones of interest. Thus, in the example illustrated, the openings are cross-shaped and delimit four rectangular portions of the protective film M11-M14 on each tile portion.

According to one embodiment, the protective film does not extend up to the edges of the tile portion, which are located in the zone of interest. This makes it possible, in the following etching step, to also remove a peripheral region of the tile portions, for example, to resize the portion. However, with a view to minimizing the loss of material, the tiles are preferably sized so as to minimize the peripheral region to be removed.

The film may be made from any appropriate resist. In particular, in the field of microelectronics, such photoresists, sold for example, by the companies Shipley or AZ Electronic Materials, are dispensed in a viscous state and spread over the substrates with the aid of spinners (known as a “spin coating” operation), then annealed. A UV exposure step makes it possible, after developing, to retain or conversely to eliminate the exposed zones. According to a variant known as “dry film photoresist,” these resists may also be applied by lamination of a thick film, with a thickness typically of between 15 and 50 μm, supplied in the form of rolls.

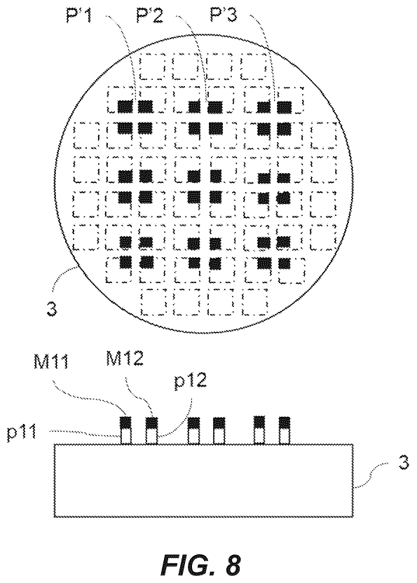

With reference to FIG. 8, an etching solution is applied to the structure in FIG. 7. The composition of the etching solution is chosen depending on the material of the tiles. For example, when the tiles are made of InP, use could be made of wet etching in a bath of hydrochloric acid (HCl) and phosphoric acid (H₃PO₄). Use could also be made of plasma etching based on halogenated gases (based on chlorine, for example, or on methane/dihydrogen (CH₄/H₂) mixtures).

Advantageously, the etching solution does not attack, or hardly attacks, the material of the receiver substrate 3.

Alternatively, etching by ion-beam sputtering, for example, argon ion-beam sputtering, may also be used. In this case, the protective film is advantageously metallic.

At the end of etching, the part of the tiles that is not covered with the protective film has been removed, over all or part of the thickness of the tiles, to separate the chips.

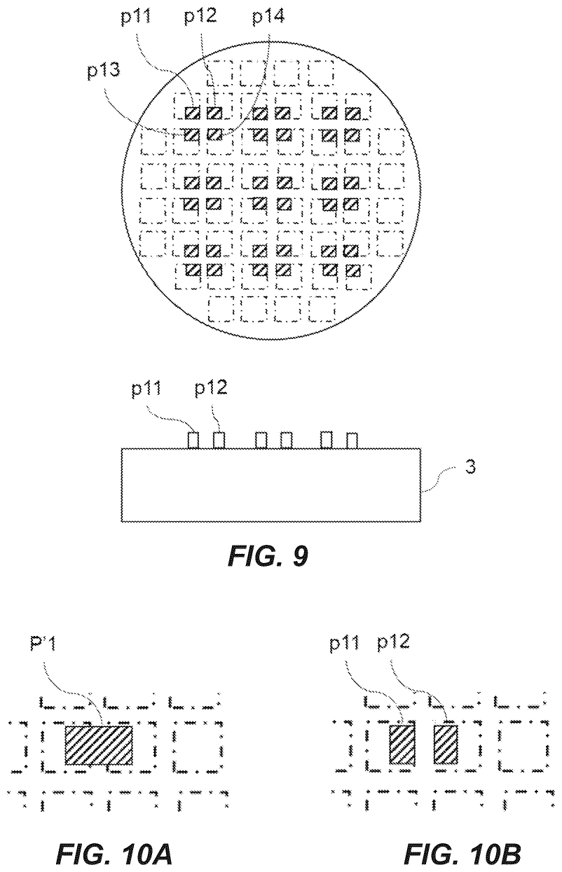

With reference to FIG. 9, the protective film is removed so as to free up the surface of the chips. The structure is therefore ready for the subsequent fabrication steps, for example, a deposition or epitaxy of one or more additional layers on the chips, the formation of electronic components in or on the chips, etc.

It will be noted that, after the formation of the chips, no chemical-mechanical polishing is carried out so as not to create inhomogeneity within the chips. In other words, any chemical-mechanical polishing step is carried out either on the pseudo-donor substrate, or on the receiver substrate after the transfer of the tile portions, but before the removal of material leading to the production of the chips. Thus, the chemical-mechanical polishing is carried out in all cases on the tiles or tile portions, which have relatively large dimensions, greater than the dimension necessary for producing the targeted chips. More specifically, each tile has a dimension greater than a multiple of the dimension of the chips that is targeted in the fabrication process. For example, each tile may have a dimension two or four times greater than the target dimension.

Multiple geometries may be obtained depending on the intended use of the final structure and the arrangement of the zones of interest.

In certain embodiments, each tile at least partially covers two different zones of interest of the receiver substrate and a chip is formed, from the tile, on each respective zone of interest.

For example, as illustrated in FIG. 10A, each tile and transferred tile portion P′1 can be arranged so as to cover a part of two adjacent zones of interest and also the surface of the receiver substrate between the zones of interest. The removal of material may be carried out so as to remove the material from each tile portion facing the surface separating the zones of interest, and, where necessary, the material of each tile portion facing each zone of interest, in order to comply with the desired geometry for each chip p11, p12 (cf. FIG. 10B).

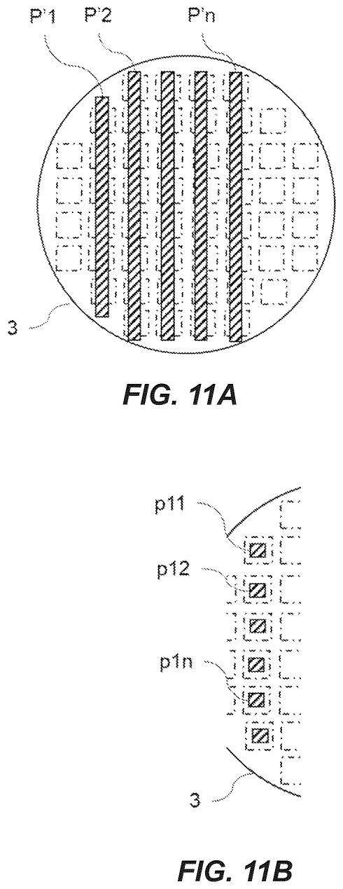

According to another example, illustrated in FIG. 11A, each tile and transferred tile portion P′1, P′2, P′n may be in the form of an elongated strip partially covering a plurality of aligned zones of interest. It is then possible to form one or more aligned chips p11, p12, p1n in each of the zones of interest belonging to the same row or column (cf. FIG. 11B).

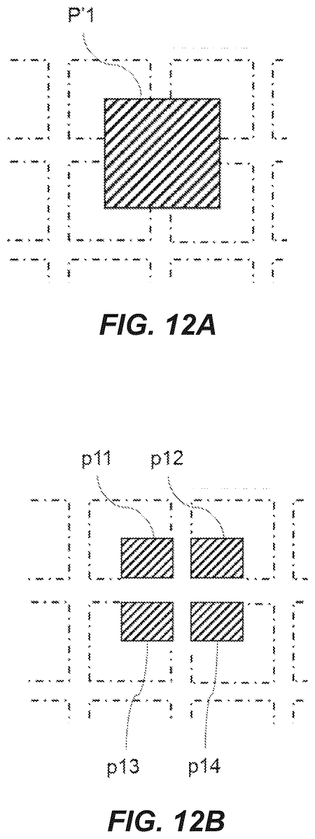

In other embodiments, as illustrated in FIG. 12A, which is an enlargement of FIG. 5, each tile and transferred tile portion P′1 may be arranged so as to cover a respective corner of four different zones of interest of the receiver substrate arranged in a square, and from the tile, a chip p11, p12, p13, p14 is formed on each corner of the respective zone of interest (cf. FIG. 12B).

Naturally, these various configurations can be combined. For example, it is possible to transfer tile portions that are oriented differently (for example, perpendicular in pairs) depending on the zones of interest to be covered.

The process therefore offers great latitude for the formation of the chips as a function of the components to be formed therefrom.

### Application Examples

The present disclosure presents different cases of particularly advantageous applications, in particular, in the field of microelectronics.

The process may make it possible to arrange chips in a not very dense manner on a 300-mm diameter receiver substrate. The receiver substrate may be a silicon substrate or a substrate of the silicon on insulator (SOI) type.

In photonic applications, the active layer of the receive a substrate may comprise a photonic circuit having passive or active devices, for example, one or more waveguides, one or more multiplexers, one or more micro-resonators, etc. The chips transferred onto this layer may be made of InP, which is a material more suitable than silicon for the epitaxial growth of a stack of III-IV materials for forming a laser.

In radiofrequency (RF) applications, the active layer of the receiver substrate may comprise components that operate at relatively low frequency, while the chips, which are advantageously made of InP or GaN, may comprise the components that operate at higher frequencies.

In micro-LED applications, the size of the GaN chips is advantageously less than 50 μm.

1. A method for manufacturing a structure comprising at least two chips on a receiver substrate, the method comprising:
forming a pseudo-donor substrate by placing at least one tile of at least one donor substrate on a support substrate;
bonding the pseudo-donor substrate to a receiver substrate via the tiles so that each tile at least partially covers at least two different zones of interest of the receiver substrate;
transferring a portion of the tiles to the receiver substrate;
at least one step of chemical-mechanical polishing of the tiles of the pseudo-donor substrate and/or of the tile portions transferred to the receiver substrate; and
after the at least one step of chemical-mechanical polishing, a removal of material from the tile portions so as to divide each tile portion into at least two chips each arranged on a respective zone of interest.

2. The method of claim 1, wherein, after the removal of material from the tile portions, a degree of coverage of the chips on the receiver substrate is less than 50%.

3. The method of claim 1, wherein a degree of coverage of the tiles on the pseudo-donor substrate is greater than 50%.

4. The method of claim 1, wherein each tile has a side with a length greater than or equal to 5 mm.

5. The method of claim 1, wherein each chip has a side with a length less than or equal to 5 mm.

6. The method of claim 1, wherein the distance between two adjacent tiles is less than or equal to 3 mm.

7. The method of claim 1, wherein the distance between two adjacent chips is greater than or equal to 3 mm.

8. The method of claim 1, wherein each tile at least partially covers two different zones of interest of the receiver substrate and a chip is formed, from the tile, on each respective zone of interest.

9. The method of claim 1, wherein each tile covers at least a respective corner of four different zones of interest of the receiver substrate arranged in a square or in a rectangle, and a chip is formed, from the tile, on each corner of the respective zone of interest.

10. The method of claim 1, wherein each tile is in the form of a strip at least partially covering at least three aligned zones of interest of the receiver substrate and a chip is formed, from the tile, on each respective zone of interest.

11. The method of claim 1, wherein the support substrate and the receiver substrate have substantially identical diameters, greater than the diameter of the donor substrate.

12. The method of claim 1, wherein the pseudo-donor substrate is bonded to the receiver substrate by molecular adhesion.

13. The method of claim 1, wherein the transfer of each tile portion comprises, in succession, forming a weakened zone by implanting atomic species in each tile of the pseudo-donor substrate to define a tile portion to be transferred, bonding the pseudo-donor substrate to the receiver substrate via the tiles, and detaching each tile along the weakened zone.

14. The method of claim 1, wherein the transfer of each tile portion comprises a thinning by grinding and/or etching of each tile of the pseudo-donor substrate.

15. The method of claim 1, wherein each tile has a thickness of between 20 μm and 1000 μm, and the transferred portion of each tile has a thickness of between 30 nm and 1.5 μm.

16. The method of claim 1, wherein each tile comprises:
a semiconductor material;
a piezoelectric material; and/or
an electrically insulating material.

17. The method of claim 1, further comprising forming, by epitaxy, at least one epitaxial layer on each tile portion before the removal of the material from the tile portions.

18. The method of claim 1, wherein the removal of the material from the tile portions comprises:
forming a mask comprising a protective film partially covering the tile portions in a pattern defining the chips in each tile portion and at least one opening defining a space to be formed between two chips; and
etching each tile portion through each opening of the mask so as to form the space for separating the chips from one another.

19. The method of claim 18, wherein the etching is carried out using an etching solution and the mask is formed of a photoresist.

20. The method of claim 18, wherein the etching is carried out using an ion beam and the mask is formed of a metal.

21. The method of claim 1, wherein the removal of the material from the tile portions is carried out selectively by a focused ion beam, the focused ion beam being controlled to sweep only the regions of the tile portions to be removed.
